(19) United States
(12) Patent Application Publication
(10) Pub. No.: US 2014/0313682 A1
(43) Pub. Date: Oct. 23, 2014

(54) COMPOSITE ELECTRONIC COMPONENT

(71) Applicant: NIHON DEMPA KOGYO CO., LTD., Tokyo (JP)

(72) Inventor: HIROYUKI MITOME, SAITAMA (JP)

(73) Assignee: NIHON DEMPA KOGYO CO., LTD., Tokyo (JP)

(21) Appl. No.: 14/257,006

(22) Filed: Apr. 21, 2014

(30) Foreign Application Priority Data
Apr. 22, 2013 (JP) 2013-089028

(51) Int. Cl. H05K 1/02

(52) U.S. Cl. CPC H05K 1/0296; H05K 2201/09372
USPC 361/767

(57) ABSTRACT

A composite electronic component includes a metal component with a wide surface terminal, a printed circuit board with a wide surface mounting pad; and a plurality of small area solder films partitioned into small sectioned regions. The small sectioned regions are sectioned by grid-shaped solder resist banks on the wide surface mounting pad. A cream solder is applied on the individual small sectioned regions to form the plurality of small area solder films. The grid-shaped solder resist bank has a width configured to: reduce a bubble that occurs in the sectioned region at one side of the grid-shaped solder resist bank from merging with a bubble that occurs in the sectioned region at another side of the grid-shaped solder resist bank; and act as an escaping route for a bubble that occur in the small area solder film.

### CROSS REFERENCE TO RELATED APPLICATIONS

This application claims the priority benefit of Japan application serial no. 2013-089028, filed on Apr. 22, 2013. The entirety of the above-mentioned patent application is hereby incorporated by reference herein and made a part of this specification.

### TECHNICAL FIELD

This disclosure relates to a composite electronic component where a housing of a large metal component is mounted on a large surface mounting portion on a wiring board by soldering.

### DESCRIPTION OF THE RELATED ART

There is known a composite electronic component where a plurality of electronic components are surface mounted on a single wiring board. The composite electronic component includes electronic components such a chip resistor, chip capacitor, and IC chip along with a large electronic component with a footprint (mounting pad) size significantly different from the sizes of the other electronic components.

Large electronic components include a composite electronic component where a large sized metal component is mounted along with other chip components on a printed circuit board by soldering. The large sized metal component includes a metal housing where the whole or the large portion of its wide surface (outer wall, sidewall, or similar surface) is used as an electrode for mounting (hereinafter referred to as wide surface terminal). A metal component of this type covers components with a wide surface terminal of 4 mm² or more and 10 mm² or more in some cases. A metal component of with similar problems, which will be described later, may have an equal to or smaller wide surface terminal. A typical surface mount component has a terminal size of 1 mm² or less. On a printed circuit board side that includes a large metal component with the above-described wide surface terminal as a mounting electrode, a mounting pad (hereinafter referred to as wide surface mounting pad) that corresponds to the size of the wide surface terminal is soldered for mounting. A surface of a soldering target, which becomes a wide surface terminal of a metal housing of a large metal component, is flat. A wide surface mounting pad of a printed circuit board also has a flat surface. Between these wide surface terminal and wide surface mounting pad, a solder film, which is formed by application of a cream solder, is interposed, and the both sides are bonded by going through a reflow furnace.

FIG. 10 is an outline perspective view illustrating a crystal controlled oscillator, which is a composite electronic component including a so-called CAN package type (lead type) crystal resonator. The crystal resonator is a large metal component where a metal housing hermetically seals a crystal element. FIGS. 11A and 11B are developed perspective views illustrating an assembly structure of the crystal controlled oscillator of FIG. 10. FIG. 11A is a view viewed from the top, and FIG. 11B is a view viewed from the bottom. This crystal controlled oscillator 30 includes a crystal resonator 20, which is a large metal component, on a printed circuit board 1 along with electronic components 6 such as a chip resistor. An output terminal 23 of the crystal resonator 20 is soldered to a crystal terminal 15 on the printed circuit board 1. On the back face (the face opposite from the mounting surface of the crystal resonator 20) of the printed circuit board 1, an IC chip 14, which constitutes active elements of an oscillation circuit, and other components are mounted.

These oscillation-circuit-constituting elements, such as the crystal resonator 20, the electronic components 6, the IC chip 14, are mounted on the printed circuit board 1, and the printed circuit board 1 is pier mounted with a space from a base 7 by using pillar shape electrode terminals 8. An open end (lower end) of the pillar shape electrode terminal 8 is for the connection with a mounting board of an applicable device. The printed circuit board 1 with electronic components is covered by a cover 31, which is also secured to the base 7.

FIGS. 12A and 12B are a plan view viewed from the crystal resonator side and a cross-sectional view. FIGS. 12A and 12B illustrate an exemplary configuration of the printed circuit board illustrated in FIGS. 11A and 11B. Here, only the mounting pads in the main area are illustrated. This printed circuit board 1 is an insulation plate that includes a glass epoxy plate or ceramic plate with a rectangular shape in a plan view. In the large portion of the central region in the printed circuit board 1, a wide surface mounting pad 11 is formed for mounting a crystal resonator. On the wide surface mounting pad 11 and the crystal terminals (terminal pads) 15 of the output terminals 23, cream solder films 5 are applied. For the areas other than these wide surface mounting pad and other soldered pads, a solder resist is applied. This similarly applies to the later described embodiment of this disclosure. As illustrated in FIG. 10 and FIGS. 11A and 11B, the metal housing of the crystal resonator 20 includes a longitudinal side surface with a transition curved surface (chamfering) between a pair of sidewall surfaces intersecting vertically to the longitudinal side surface. Compared with the cream solder film 5 on the wide surface mounting pad 11, an outer line of the crystal resonator 20, which is illustrated with a dotted line in FIG. 12, is positioned outside the cream solder film 5. To the crystal terminals 15, the output terminals 23 (FIG. 10) of the crystal resonator 20 are connected.

In this crystal controlled oscillator 30, the lead type crystal resonator 20 includes a housing with a flat side wall solder bonded to the wide surface mounting pad 11 of the printed circuit board 1. For the bonding, the cream solder film 5, which is formed by applying a cream solder all over the wide surface mounting pad 11, is formed, and the printed circuit board 1 is put through a reflow process. In some cases, the metal housing 22 is used as an earthing terminal. The area of the cream solder film 5, where a cream solder is applied all over, is considerably larger than areas of ordinary electrode pads such as bonding pads for chip components. Because of this, escape destination is limited for the bubbles formed in vaporization of melted flux, which is contained in solder, at a reflow process. Especially, the central region of the solder film has no escape passages for bubbles, and a large amount of voids are formed in this area. According to the IPC-A-610 specification, the total void area should be less than 25% of the pad area. However, for a large area solder bonding such as for the lead type crystal resonator 20, the total void area is very likely to exceed 25% of the pad area.

Possible problems of enlarged void areas include melted solder splashes and component shifts at a repeated reflow of a mounted board at a customer's side. These solder splashes and component shifts could cause an initial failure. Another possible problem of the enlarged void areas is formation of a crack with heat cycles.

A known conventional technique as a countermeasure for such problems is to partition a pad surface by a solder resist and let formed bubbles escape easily out of solder films (See Japanese Unexamined Patent Application Publication No. 2006-261356, for example). Also, another conventional technique is to form a circular shape cutout area in the center of an electrode pad to let voids to concentrate in this cutout area (See Japanese Unexamined Patent Application Publication No. 08-274211).

Bubbles causing voids are mostly formed from evaporation of solder flux. The bubbles stay in melted solder, remain in a solder film even after the solder hardens, and form voids. Formed bubbles are considerably small at first, but a plurality of considerably small bubbles merge with each other and grow to a bigger bubble. This bigger bubble becomes a large void and remains in a solder film. Such a void then reduces an electrode area to be bonded by soldering and causes various bonding failures.

Partly by composition of solder, the amount of bubbles that cause voids differs. Even with some differences, bubbles form in melted solder. As the area of a bonding terminal or a bonding pad becomes larger, escape passages for bubbles become more limited, and more bubbles are trapped in melted solder. In general, bubbles have a characteristic of merging together. As a continuous solder film area gets larger, bubbles merge more and cause formation of bigger voids. This disclosure covers an electronic component equipped with a printed circuit board that includes a wide surface mounting pad with a large area for mounting a large metal component. In this type of the electronic component, bubbles are significantly suppressed to escape and thus form voids. Although the above-described Japanese Unexamined Patent Application Publication No. 2006-261356 discloses the number of partitions made by a solder resist on a pad, the number of partitions on the pad is restricted by the size of the pad itself and the minimum width of a printable solder resist. Increasing the number of partitions on a small electrode pad would cause melted solder to merge beyond the solder resist and grow voids. Thus, applying solder resist on a small mounting pad in too detail would lower the effect. Even with the conventional technique disclosed in the above-described Japanese Unexamined Patent Application Publication No. 2006-261356, there is a limitation on the size of the cutout area of the solder application area, considering the balance with solder bonding strength.

A need thus exists for a composite electronic component which is not susceptible to the drawbacks mentioned above.

### SUMMARY

A composite electronic component according to the disclosure includes an electronic component, a metal component, a printed circuit board, and a plurality of small area solder films. The electronic component includes a mounting pad. The metal component includes a wide surface terminal. The wide surface terminal has a wider area than an area of the mounting pad. The printed circuit board includes a wide surface mounting pad corresponding to the mounting pad and the wide surface terminal. The plurality of small area solder films are partitioned into small sectioned regions. The small sectioned regions are sectioned by grid-shaped solder resist banks on the wide surface mounting pad. A cream solder is applied on the individual small sectioned regions to form the plurality of small area solder films. The grid-shaped solder resist bank has a width configured to: reduce a bubble that occurs in the sectioned region at one side of the grid-shaped solder resist bank from merging with a bubble that occurs in the sectioned region at another side of the grid-shaped solder resist bank; and act as an escaping route for a bubble that occur in the small area solder film.

### BRIEF DESCRIPTION OF THE DRAWINGS

The foregoing and additional features and characteristics of this disclosure will become more apparent from the following detailed description considered with the reference to the accompanying drawings.

FIG. 1 is a perspective view schematically illustrating a composite electronic component according to an embodiment 1 of this disclosure.

FIG. 2 is an enlarged plan view of the section selected with a circle A in FIG. 1.

FIG. 3 is a perspective view schematically illustrating a composite electronic component according to an embodiment 2 of this disclosure.

FIG. 4 is a schematic diagram illustrating a cross-sectional view taken along the line IV-IV of FIG. 3.

FIGS. 5A and 5B are explanatory views illustrating an exemplary configuration with a wide surface mounting pad disposed on a printed circuit board, FIG. 5A is a plan view viewed from a lead type crystal resonator 20, and FIG. 5B is a cross-sectional view taken along the line VB-VB of FIG. 5A.

FIG. 6A is a plan view illustrating a state of cream solder applied between solder resist grids illustrated in FIGS. 5A and 5B, and FIG. 6B is a cross-sectional view taken along the line VIB-VIB of FIG. 6A.

FIGS. 7A and 7B are reproductions of X-ray photographs illustrating voids remaining in solder films after bonding to illustrate the effect of the embodiment 2 according to this disclosure in comparison with the effect of the conventional technique.

FIG. 8 is a perspective view schematically illustrating a composite electronic component according to an embodiment 3 of this disclosure.

FIG. 9 is a schematic diagram illustrating a cross-sectional view taken along the line IX-IX of FIG. 8.

FIG. 10 is an outline perspective view illustrating a crystal controlled oscillator, which is a composite electronic component including a so-called CAN package type (lead type) crystal resonator where a metal housing hermetically seals a crystal element, as a large metal component.

FIGS. 11A and 11B are developed perspective views illustrating an assembly structure of a crystal controlled oscillator of FIG. 10, FIG. 11A is a developed perspective view viewed from the top, and FIG. 11B is a developed perspective view viewed from the bottom.

FIG. 12A is a plan view viewed from the crystal resonator side and illustrates an exemplary configuration of the printed circuit board illustrated in FIGS. 11A and 11B, and FIG. 12B is a cross-sectional view taken along the line XIIB-XIIB of FIG. 12A.

### DETAILED DESCRIPTION

### Embodiment 1

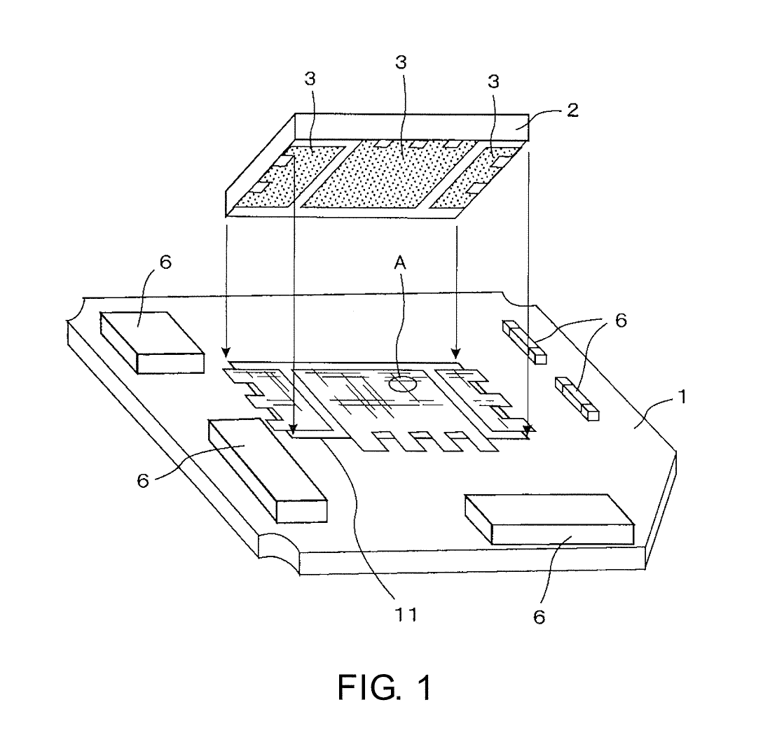

FIG. 1 is a perspective view schematically illustrating a composite electronic component according to an embodiment 1 of this disclosure. This composite electronic component includes a metal component 2 on a printed circuit board 1 along with common electronic components 6 such as a chip resistor and chip capacitor. The common electronic components 6 are mounted on pads formed at predetermined positions on the printed circuit board 1 by solder bonding. While these are bonded by FCA (Flip Chip Attach), pin deposition and other soldering are used for mounting.

Unlike the other electronic components 6, the metal component 2 includes a wide surface terminal 3, which has a surface considerably larger than terminals of other electronic components 6, on a partial surface of the metal component 2. The metal component 2 illustrated in FIG. 1 is entirely molded with resin, and a wide surface terminal 3, which is a metal terminal, is formed on a large portion of its one surface. Here, for convenience, the metal component 2 is referred to as a “metal component.”

On the most portion of the central region on the printed circuit board 1, a wide surface mounting pad 11 is formed in a position corresponding to the wide surface terminal 3, which is disposed on the metal component 2. In this embodiment, the wide surface mounting pad 11 is on the surface of the printed circuit board 1 and is formed by gold plating on a metal film patterned with a copper foil. On this wide surface mounting pad 11, a solder resist in a grid shape and a plurality of small solder films, which are partitioned by the solder resist banks, are applied. Solder resist may be applied by, for example, silk screen printing.

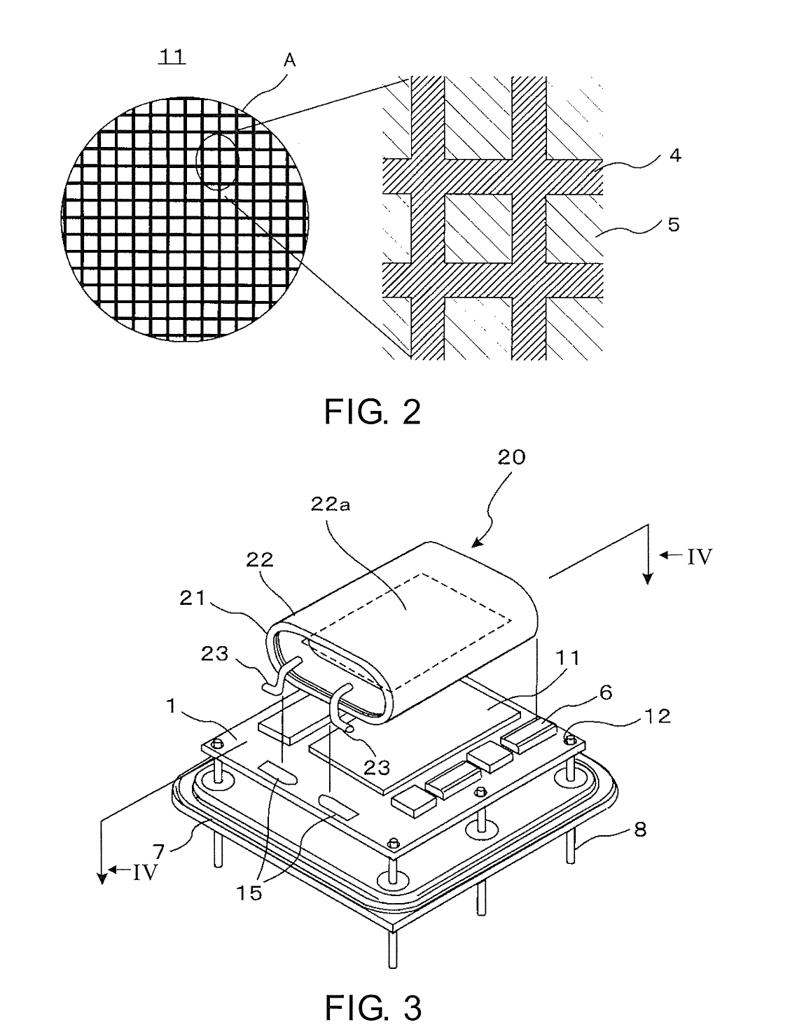

FIG. 2 is an enlarged plan view of the section selected by a circle A in the FIG. 1. This embodiment illustrates a state where the cream solder films 5 are applied to the small sections partitioned by the banks of solder resist 4, which is applied in the grid shape. For this cream soldering application, a printing using metal masking and a squeegee is preferred.

On the wide surface mounting pad 11 of the printed circuit board 1, the cream solder films 5 are applied in the small sections partitioned by the banks of the solder resist 4. On the wide surface mounting pad 11, the wide surface terminal 3 of the metal component 2 is positioned, and the wide surface mounting pad 11 with the wide surface terminal 3 along with other electronic components 6 are put through a reflow furnace. This bonds the wide surface terminal 3 and the wide surface mounting pad 11 with the cream solder films 5 that get melted and then hardened. At this time, other electronic components are similarly bonded by soldering.

During the reflow process by the reflow furnace, if bubbles are formed from the cream solder films 5 applied on the small sections partitioned by the banks of the solder resist 4, the formed bubbles escape through the solder resist 4. This makes the bubbles to move to adjacent small sections difficult. Because of this, the bubbles in solder films in respective small sections are prevented from moving to each other or from one place to the other and also prevented from growing.

With this embodiment, the wide surface terminal 3 of the metal component 2 and the wide surface mounting pad 11 of the printed circuit board 1 are uniformly bonded and strongly secured. Furthermore, even if the printed circuit board goes through a repeated reflow process at a customer's side, splashes or component shifts caused by voids are suppressed.

### Embodiment 2

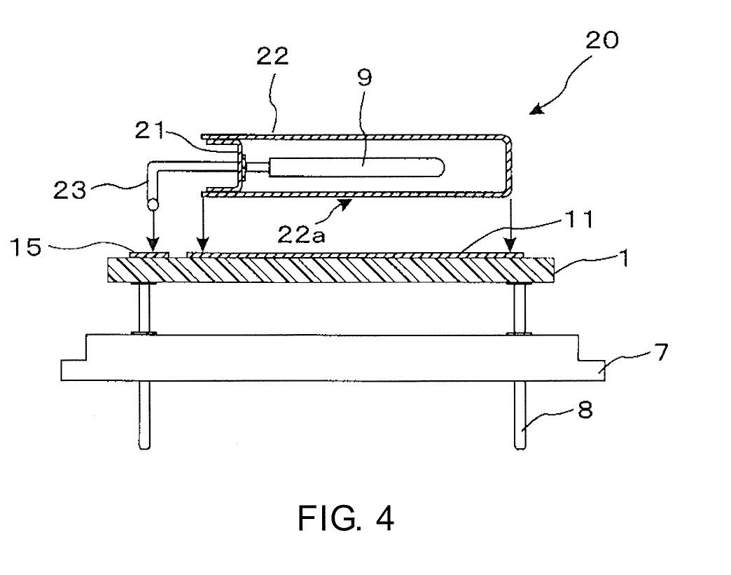

FIG. 3 is a perspective view schematically illustrating a composite electronic component according to an embodiment 2 of this disclosure. This composite electronic component is an exemplary crystal controlled oscillator, which is a composite electronic component with a lead type crystal resonator. FIG. 4 is a schematic diagram illustrating a cross-sectional view taken along the line IV-IV of FIG. 3. In FIG. 3 and FIG. 4, reference numeral 1 denotes a printed circuit board, reference numeral 6 denotes known electronic components such as a chip resistor and IC chip, reference numeral 7 denotes a device base (base), reference numeral 8 denotes a pillar shape electrode terminal, reference numeral 11 denotes a wide surface mounting pad, reference numeral 12 denotes a through hole, reference numeral 15 denotes a crystal terminal, reference numeral 20 denotes a CAN package type (lead type) crystal resistor (hereinafter, referred to as lead type crystal resistor), reference numeral 21 denotes a stem, reference numeral 22 denotes a metal housing, reference numeral 22a denotes a flat wall surface, which becomes a sidewall surface terminal, and reference numeral 23 denotes an output terminal.

For the lead type crystal resonator 20, the flat wall surface 22a of the metal housing 22, which is used as a sidewall surface terminal (wide surface terminal), is bonded and secured by soldering to the wide surface mounting pad 11 formed on the printed circuit board 1, and the flat wall surface 22a and the wide surface mounting pad 11 are electrically connected. The flat wall surface 22a of the metal housing 22 constitutes an earth terminal of a lead type crystal resonator 20. A pair of output terminals 23 of the lead type crystal resonator 20 are bonded by soldering to the crystal terminals 15 and 15 formed on the printed circuit board 1. The metal housing 22 is molded by a metal that allows solder bonding. An example of such metals is a copper base plated with nickel and finished with tin plating.

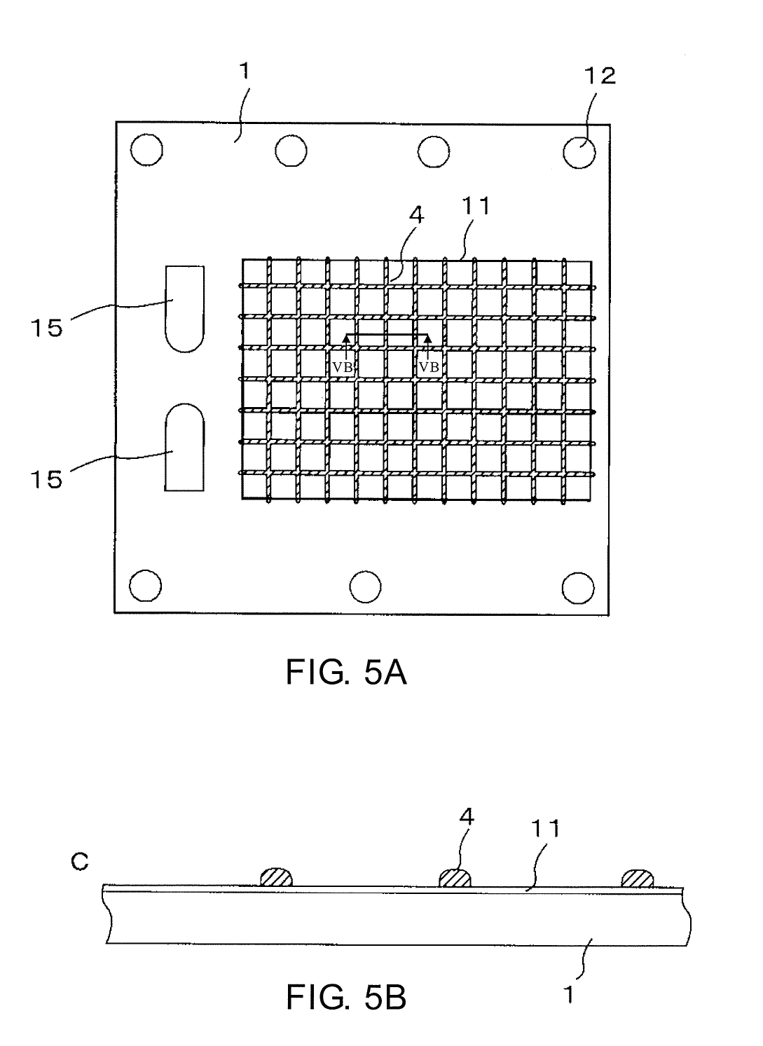

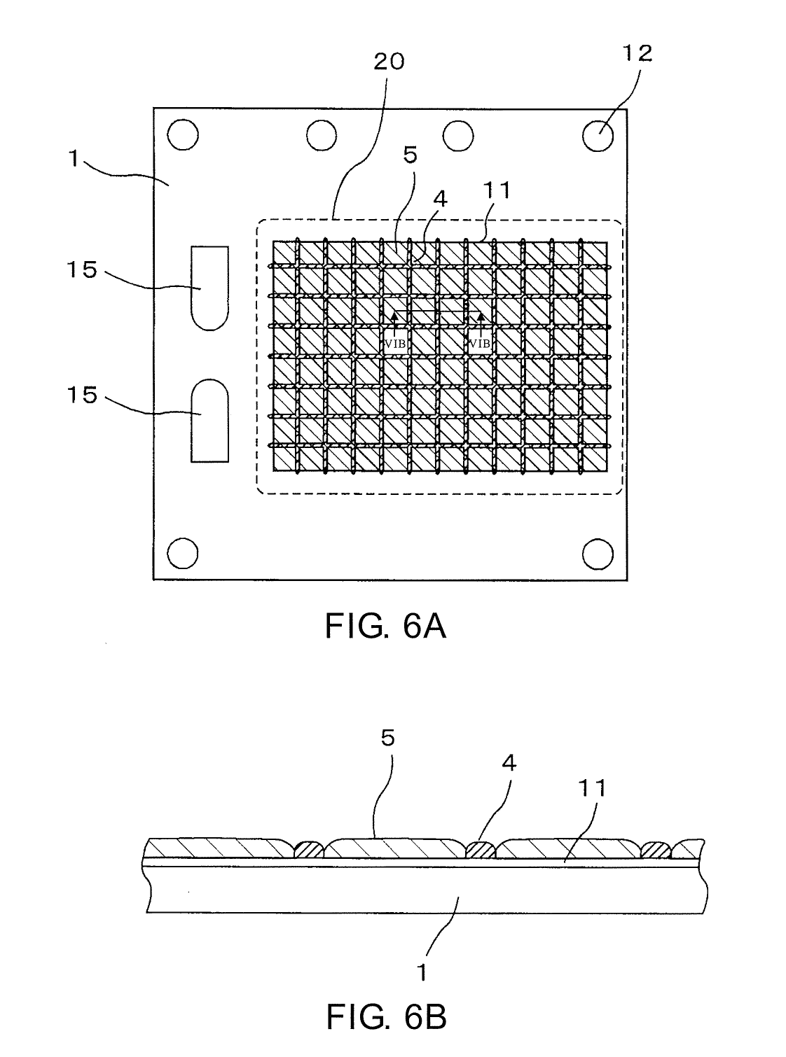

FIGS. 5A and 5B are explanatory views illustrating an exemplary configuration of a wide surface mounting pad disposed on a printed circuit board. FIG. 5A is a plan view viewed from the lead type crystal resonator 20. FIG. 5B is a cross-sectional view taken along the line VB-VB of FIG. 5A. FIGS. 6A and 6B illustrate cream solders applied between solder resist grids illustrated in FIGS. 5A and 5B. FIG. 6A is a plan view. FIG. 6B is a cross-sectional view taken along the line VIB-VIB of FIG. 6A. As illustrated by FIGS. 5A and 5B, the wide surface mounting pad 11 has a surface patterned in an electrode shape (foot plate) with a copper foil then plated by gold. On this, the solder resist 4 is applied in a grid shape by silk screen printing. In this embodiment, the grid shape of the solder resist 4 is a square.

After applying the solder resist 4 in the grid shape, as illustrated in FIGS. 6A and 6B, a cream solder is applied. Application of the cream solder is favorably performed with a metal mask that has openings between the grids of the solder resist 4. In this application process, the cream solder is applied on the metal mask placed on the solder resist 4, and the cream solder is spread with a pressure using a squeegee. The cream solder is then applied between the grids through the openings.

FIG. 6B illustrates a cross-sectional view of the wide surface mounting pad 11 where the cream solder is applied. As illustrated, the cream solder films 5 are applied between the grids of the solder resist 4. The flat wall surface 22a of the lead type crystal resonator 20 is positioned on the wide surface mounting pad 11, which has the cream solder films 5 partitioned in the small sections by the solder resist, and goes through a reflow process.

In this reflow process, solder powders constituting the cream solder films 5 get melted. In this melting process, flux constituting the cream solder films 5 generates bubbles (gas). The bubbles smaller than the small solder sections may stay in the melted solder film in the section, but relatively large bubbles escape from the small section to the solder resist 4.

Also, even if bubbles, which are formed in solder films in adjacent small sections, attempt to merge, the existence of the solder resist 4 interferes this. Consequently, the bubbles do not go under the solder film to grow into a large bubble. Even if a few small voids remain in the solder film, bonding effect is not significantly reduced. As a result, when solder is hardened, no large voids are formed in solder films, and the wide surface mounting pad 11 and the flat wall surface 22a of the lead type crystal resonator 20 are bonded by using sufficient area of the soldering film.

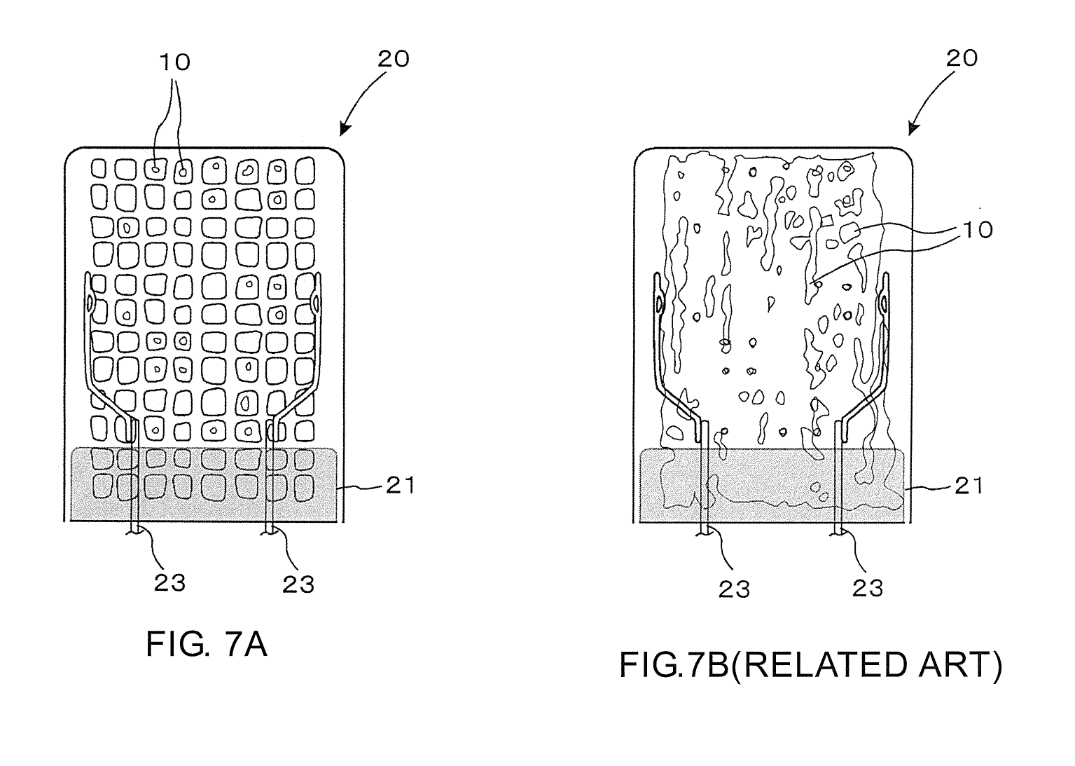

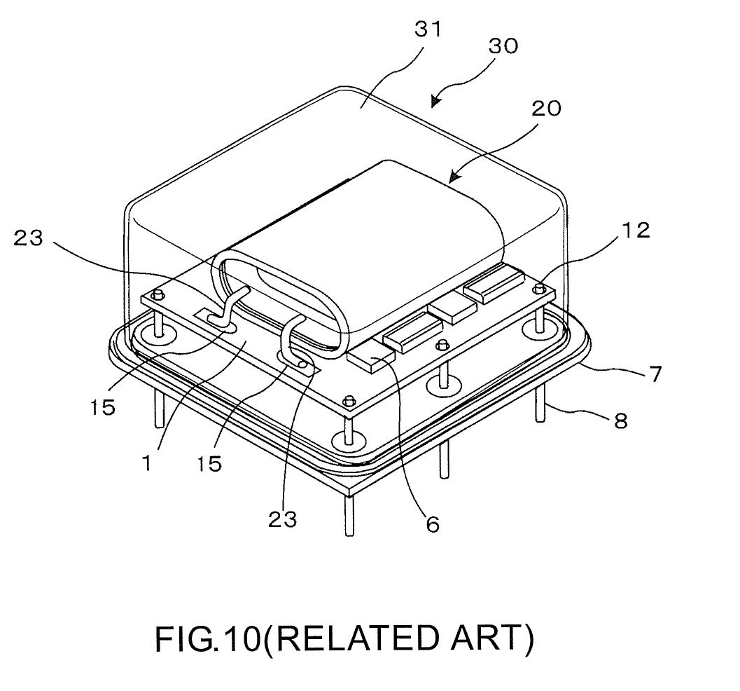

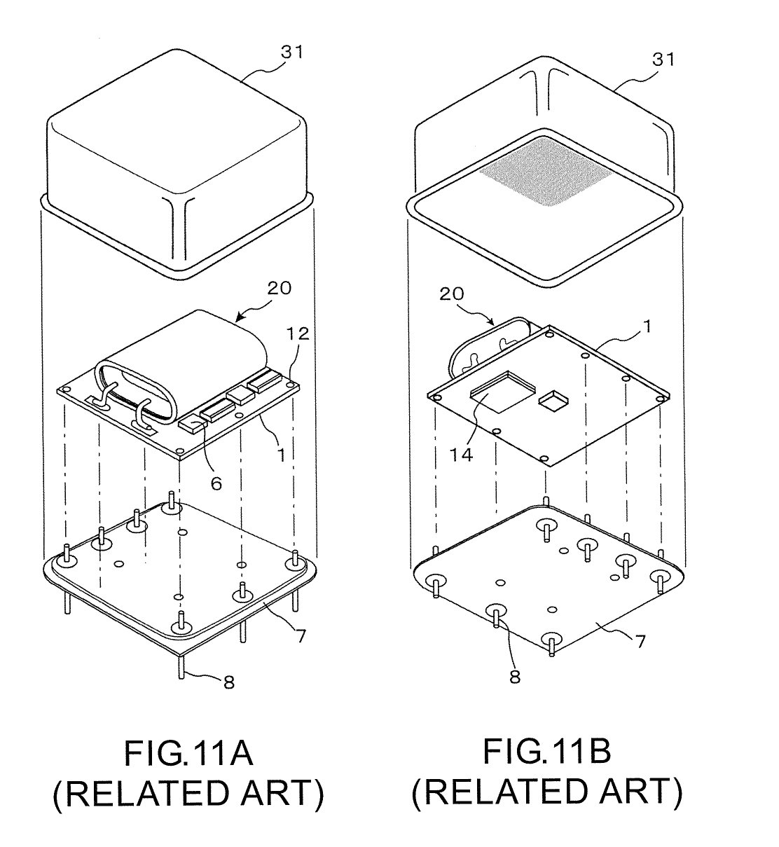

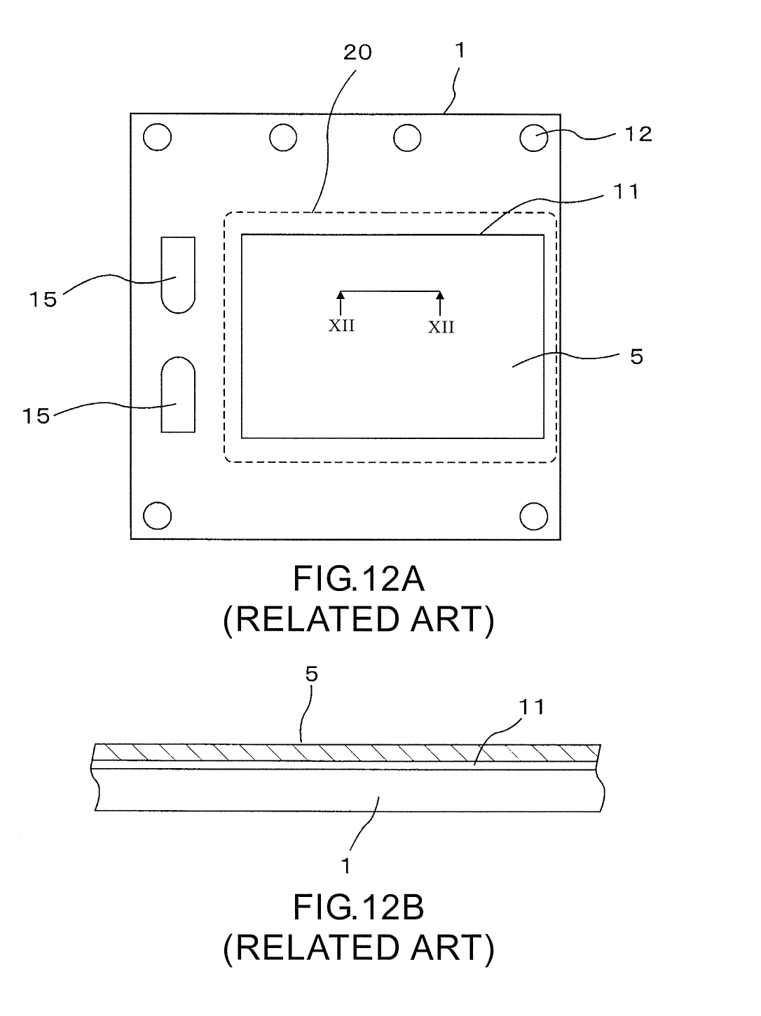

FIGS. 7A and 7B are reproductions of X-ray photographs illustrating voids remaining in solder films after bonding. FIGS. 7A and 7B illustrate the effect of the embodiment 2 according to this disclosure in comparison with the effect of the conventional technique. FIG. 7A illustrates a bonding state between the wide surface mounting pad 11 and the flat wall surface 22a of the lead type crystal resonator 20 according to embodiment 2 of this disclosure. FIG. 7B illustrates a bonding state between the wide surface mounting pad 11 and the flat wall surface 22a of the crystal resonator 20 according to the conventional technique described in FIG. 10 to FIG. 12B.

As illustrated in FIG. 7B, conventionally, a component bonded by applying cream solder all over had large voids 10 throughout the bonding surface. These voids merged and grew into different shapes and occupied a large ratio within the bonding surface. In contrast, in the embodiment 2 illustrated in FIG. 7A, although considerably small voids remain in the small sections of some places, a substantially uniform solder bonding is performed throughout the bonding surface. This effect is common to all the embodiments according to this disclosure.

Thus, with this embodiment, even in the solder bonding of the metal components with a comparably large surface, bonding failures by voids are significantly reduced. Also, the voids are kept small, and the considerably small voids are trapped in the small sectioned solder films and prevented to merge each other. Thus, bonding failures caused by solder voids at a reflow process or repeated reflow process are avoided.

### Embodiment 3

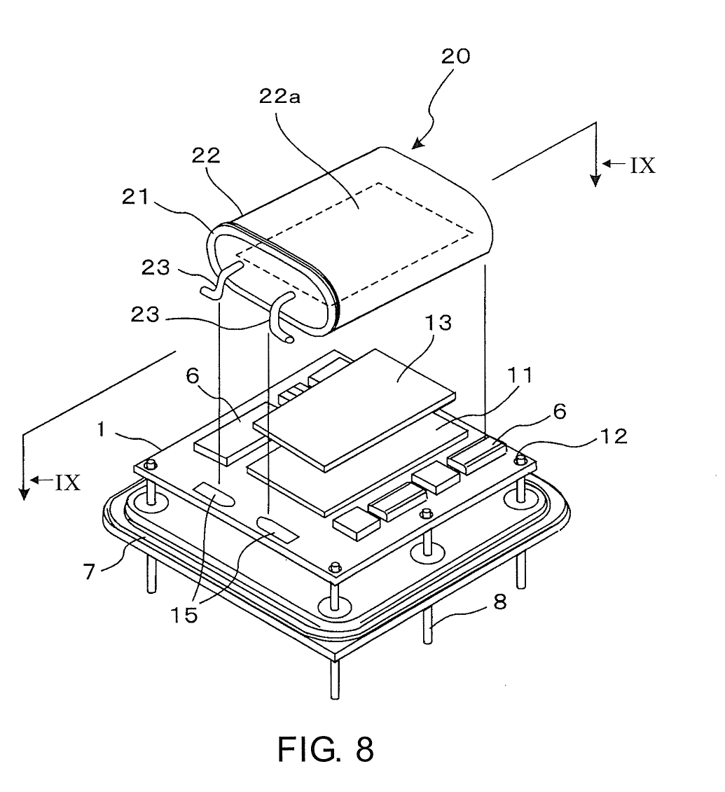

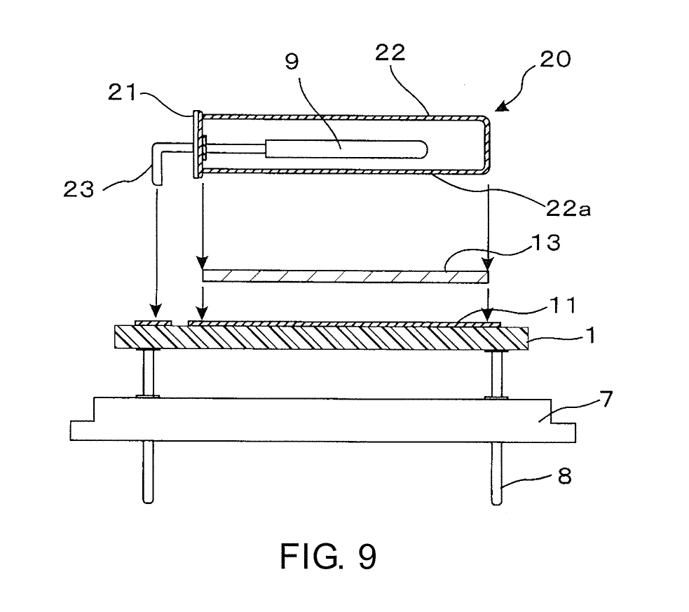

FIG. 8 is a perspective view schematically illustrating a composite electronic component according to an embodiment 3 of this disclosure. This composite electronic component is also an exemplary crystal controlled oscillator, which is a composite electronic component that has a lead type crystal resonator, similarly to the one in FIG. 3. FIG. 9 is a schematic diagram illustrating a cross-sectional view taken along the line IX-IX of FIG. 8. In FIG. 8 and FIG. 9, the same reference numerals are used for the same functional components in FIG. 3 and FIG. 4.

In the embodiment 3, the composite structure of the metal housing 22 and the stem 21 of the lead type crystal resonator 20 (flange formed end edges are caulk secured) is different from the one in the lead type crystal resonator 20 of the embodiment 2. That is, at the lead type crystal resonator 20 of the embodiment 3, the outer peripheral edge of the stem 21, which is secured to the metal housing 22, protrudes outside with respect to the opening end edge of the metal housing 22. Because of this, the flat wall surface 22a of the lead type crystal resonator 20 cannot be bonded directly to the wide surface mounting pad 11.

In this embodiment, between the flat wall surface 22a of the lead type crystal resonator 20 and the wide surface mounting pad 11 of the printed circuit board 1, a metal plate 13 is interposed and bonded by soldering. That is, the thickness of the metal plate 13 that allows solder bonding is equal to or slightly thicker than the size at the outer periphery area protruded by caulk fixing. As illustrated in FIG. 9, on the wide surface mounting pad 11 of the printed circuit board 1, the metal plate 13 is placed. At this time, on the wide surface mounting pad 11, a cream solder partitioned into the small sections by the grid-shape solder resist similar to the above-described embodiments is applied. The printed circuit board is put through a reflow process and bonded.

Next, on the metal plate 13, a cream solder, which is partitioned into the small sections by the similar grid-shape solder resist, is applied. On top of the cream solder, the flat wall surface 22a of the crystal resonator 20 is positioned, and put through a reflow process again. This process allows the lead type crystal resonator 20 containing a caulked flange to be mounted on the printed circuit board 1. The metal plate 13 is molded by a metal capable of solder bonding. An example of such metals is a copper base plated with nickel and finished with tin plating.

The structure of this embodiment is different from the embodiment 2 in that a metal plate 13 is interposed between the lead type crystal resonator 20 and the printed circuit board 1. However, the shapes and effects of the bubbles formed and the voids remaining in the melted cream solder at a reflow process are similar to the embodiment 2, and redundant descriptions are omitted. Edge portions of the solder resist applied in the grid shape may be extended and disposed slightly toward the outer edge with respect to the cream solder applying region, so as to prevent the melted solder from merging at the edge portions and secures escape passages for bubbles. Also, when using solder that has significantly low formation of bubbles, the edge portions of the solder resist may be slightly retracted from the solder applying region, then actively merge the melted solder over the edge portions to have a large bonding area.

While in the respective above-described embodiments the solder resist is applied to form banks in the square grid shape on the wide surface mounting pad, this should not be construed in a limiting sense. The solder resist banks may be inclined to each other to form rhombus grids and have a similar effect. Basically the banks of the solder resist may be square grids or rhombus grids, but the spacing of the grids are constant across the whole region. However, according to the bubble formation characteristic of the solder and the thermal distribution on a wide surface mounting pad, the grids may be spaced wider or narrower along a direction of the grids, a direction crossing the direction, or along both of the directions from the center of the wide surface mounting pad to the outer peripheral.

In the above-described embodiments, solder bonding of the electronic component with a wide surface terminal is described. This disclosure is not limited to electronic components and may be applied to various technical fields as long as it is a bonding between materials having a large soldering surface.

According to the disclosure, the grid-shaped solder resist banks are disposed on the wide surface mounting pad formed on a printed circuit board. Individual small sectioned regions are partitioned by these grid-shaped solder resist banks. A large number of small area solder films are formed by applying a cream solder and partitioning into the individual small sections. The solder resist film banks each have a width configured to reduce a bubble that occurs in the small area solder film, which is sectioned by the solder resist film banks, at one side of the grid-shaped solder resist bank from merging with a bubble that occurs in the solder film at another side of the grid-shaped solder resist bank. The solder resist film banks act as escaping routes for bubbles that occur in the solder film, suppresses the bubbles from merging together, reduces the amount and the number of voids, and reduces the voids from forming in the solder bonding film.

The width and spacing of the grids according to the disclosure may be experimentally determined according to a composition and a bubble formation characteristic of the used cream solder. The typical solutions to solve the problem are as follows.

(1) A composite electronic component includes: an electronic component in an ordinary size such as a chip resistor and an IC chip; a large metal component with a wide surface terminal that is considerably larger than an area of a mounting pad of the electronic component in the ordinary size; a printed circuit board with a wide surface mounting pad corresponding to the mounting pad of the electronic component in the ordinary size and the wide surface terminal of the large metal component; and a large number of small area solder films formed by applying a cream solder on individual small sectioned regions partitioned by grid-shaped solder resist banks on the wide surface mounting pad. The solder resist film banks each have a width designed to reduce a bubble that occurs in the small area solder film, which is sectioned by the solder resist film banks, at one side of the grid-shaped solder resist bank from merging with a bubble that occurs in the solder film at another side of the grid-shaped solder resist bank. The solder resist film banks act as escaping routes for bubbles that occur in the solder film.

(2) In the above-described composite electronic component (1), the grid-shaped solder resist banks are arranged in a square grid.

(3) In the above-described composite electronic component (1), the grid-shaped solder resist banks are arranged in a rhombus grid.

(4) In anyone of the above-described composite electronic components (1) to (3), the grid-shaped solder resist banks are spaced with a constant space along a direction of the grids, a direction crossing the direction of the grids, or along both of the directions.

(5) In anyone of the above-described composite electronic components (1) to (3), the grid-shaped solder resist banks are spaced with a gradually changing space along a direction of the grids, a direction crossing the direction of the grids, or along both of the directions toward the outer peripheral of the wide surface mounting pad.

(6) In the above-described composite electronic component (5), the grid-shaped solder resist banks are spaced with a gradually increasing space along a direction of the grids, a direction crossing the direction of the grids, or along both of the directions toward the outer peripheral of the wide surface mounting pad.

(7) In the above-described composite electronic component (5), the grid-shaped solder resist banks are spaced with a gradually decreasing space along a direction of the grids, a direction crossing the direction of the grids, or along both of the directions toward the outer peripheral of the wide surface mounting pad.

(8) In anyone of the above-described composite electronic components (1) to (7), the grid-shaped solder resist bank has an end portion that protrudes outside from an edge of a solder resist applied region.

The disclosure is not limited to the above-described embodiments insofar as an electronic component (which is also referred to as metal component) to be mounted on a print circuit board includes a housing or external wall having a metallic material with a wide surface that allows solder bonding, and the housing or external wall is to be mounted on the wide surface mounting pad formed on the print circuit board.

During a reflow process, the bubbles are formed by melting a plurality of small area solder films partitioned by solder resist banks. Naturally, those bubbles do not exceed the respective sizes of the small area solder films. Even if the bubbles formed from melting of respective small area solder films go out of the sections of the small area solder films, due to the solder resist banks, those bubbles do not merge and grow with other bubbles formed in adjacent small sections. This disclosure prevents initial failures caused by above-described re-melted solder splashes and component shifts at a repeated reflow at a customer's side. This disclosure also prevents generation of cracks with years of heat cycles.

With this disclosure, the voids are kept small and also prevented from merging. Thus, the bonding failures caused by solder voids at a reflow process or repeated reflow process are avoided.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A composite electronic component, comprising:
an electronic component with a mounting pad;
a metal component with a wide surface terminal, the wide surface terminal having a wider area than an area of the mounting pad;
a printed circuit board with a wide surface mounting pad corresponding to the mounting pad and the wide surface terminal; and
a plurality of small area solder films partitioned into small sectioned regions, the small sectioned regions being sectioned by grid-shaped solder resist banks on the wide surface mounting pad, a cream solder being applied on the individual small sectioned regions to form the plurality of small area solder films, wherein
the grid-shaped solder resist bank has a width configured to:
reduce a bubble that occurs in the sectioned region at one side of the grid-shaped solder resist bank from merging with a bubble that occurs in the sectioned region at another side of the grid-shaped solder resist bank; and
act as an escaping route for a bubble that occur in the small area solder film.

2. The composite electronic component according to claim 1, wherein
the grid-shaped solder resist banks are arranged in a square grid.

3. The composite electronic component according to claim 1, wherein
the grid-shaped solder resist banks are arranged in a rhombus grid.

4. The composite electronic component according to claim 1, wherein
the grid-shaped solder resist banks are spaced with a constant space along a direction of the grids, a direction crossing the direction of the grids, or along both of the directions.

5. The composite electronic component according to claim 1, wherein
the grid-shaped solder resist banks are spaced with a gradually changing space along a direction of the grids, a direction crossing the direction of the grids, or along both of the directions toward the outer peripheral of the wide surface mounting pad.

6. The composite electronic component according to claim 4, wherein
the grid-shaped solder resist banks are spaced with a gradually increasing space along a direction of the grids, a direction crossing the direction of the grids, or along both of the directions toward the outer peripheral of the wide surface mounting pad.

7. The composite electronic component according to claim 4, wherein
the grid-shaped solder resist banks are spaced with a gradually decreasing space along a direction of the grids, a direction crossing the direction of the grids, or along both of the directions toward the outer peripheral of the wide surface mounting pad.

8. The composite electronic component according to claim 1, wherein
the grid-shaped solder resist bank has an end portion that protrudes outside from an edge of a solder resist applied region.
